(19) United States
(12) Patent Application Publication
(10) Pub. No.: US 2022/0352372 A1
(43) Pub. Date: Nov. 3, 2022

(54) SEMICONDUCTOR DEVICE AND MANUFACTURING METHOD THEREOF

(71) Applicant: CHANGXIN MEMORY TECHNOLOGIES, INC., Hefei City (CN)

(72) Inventors: Jie BAI, Hefei City (CH); Wenli ZHAO, Hefei City (CN)

(21) Appl. No.: 17/454,152

(22) Filed: Nov. 9, 2021

Related U.S. Application Data
(63) Continuation of application No. PCT/CN2021/110116, filed on Aug. 2, 2021.

(30) Foreign Application Priority Data
Apr. 30, 2021 (CN) 20110486503.4

(51) Int. Cl. H01L 29/78; H01L 27/092; H01L 21/8238; H01L 29/161

(52) U.S. Cl. CPC H01L 29/7848; H01L 27/092; H01L 21/823828; H01L 21/823857; H01L 29/161

(57) ABSTRACT

Embodiments of the present application provide a semiconductor device and a method of manufacturing semiconductor device. The semiconductor device includes a substrate, a silicon-germanium (SiGe) epitaxial layer, a protective layer, and a positive-channel metal-oxide semiconductor (PMOS) gate; a surface of the substrate includes at least a PMOS region; the SiGe epitaxial layer is grown on the surface of the substrate and located in the PMOS region; the protective layer covers a surface of the SiGe epitaxial layer; the PMOS gate is located on a surface of the protective layer.

### CROSS-REFERENCE TO RELATED APPLICATIONS

This is a continuation of International Patent Application No. PCT/CN2021/110116, filed on Aug. 02, 2021, which claims the priority to Chinese Patent Application No. 202110486503.4, titled “SEMICONDUCTOR DEVICE AND MANUFACTURING METHOD THEREOF” and filed to the China National Intellectual Property Administration on Apr. 30, 2021. The entire contents of International Patent Application No. PCT/CN2021/110116 and Chinese Patent Application No. 202110486503.4 are incorporated herein by reference.

### TECHNICAL FIELD

The present application relate to the technical field of semiconductors, and in particular, to a semiconductor device and a method of manufacturing semiconductor device.

### BACKGROUND

As a size of a metal-oxide-semiconductor field-effect transistor (MOSFET) tends to be miniaturized, a high-k metal gate (HKMG) technology has been widely used in a MOSFET manufacturing process.

In an existing HKMG-based MOSFET manufacturing process, a silicon-germanium (SiGe) epitaxial layer usually needs to be formed in source and drain regions of a positive-channel metal-oxide semiconductor (PMOS) device. The SiGe epitaxial layer can modulate stress in a channel region of the PMOS device, thereby helping improve carrier mobility of the PMOS device, and thus improving electrical properties of the PMOS device.

However, the existing manufacturing process easily damage the formed SiGe epitaxial layer after the formation of the SiGe epitaxial layer, resulting in reduced carrier mobility, and affecting the electrical properties of the PMOS device.

### SUMMARY

Embodiments of the present application provide a semiconductor device and a method of manufacturing semiconductor device thereof.

According to a first aspect, the present application provides a method of manufacturing semiconductor device, where the method of manufacturing semiconductor device includes:

obtaining a substrate, where a surface of the substrate includes at least a PMOS region;

growing a SiGe epitaxial layer in the PMOS region;

forming a protective layer on a surface of the SiGe epitaxial layer; and

preparing a PMOS gate based on the SiGe epitaxial layer with the protective layer, to obtain a target PMOS device.

According to a second aspect, an embodiment of the present application provides a semiconductor device, where the semiconductor device includes:

a substrate, where a surface of the substrate includes at least a PMOS region;

a SiGe epitaxial layer, grown on the surface of the substrate and located in the PMOS region;

a protective layer, covering a surface of the SiGe epitaxial layer; and

a PMOS gate, located on a surface of the protective layer.

### BRIEF DESCRIPTION OF THE DRAWINGS

To describe the technical solutions in the embodiments of the present application or in the prior art more clearly, the following briefly describes the accompanying drawings required for describing the embodiments of the present application or the prior art. Apparently, the accompanying drawings in the following description show some embodiments of the present application, and those of ordinary skill in the art may still derive other drawings from these accompanying drawings without creative efforts.

FIG. 1 is a schematic flowchart of a method of manufacturing semiconductor device according to an embodiment of the present application;

FIG. 2 is a schematic flowchart of another method of manufacturing semiconductor device according to an embodiment of the present application; and

FIG. 3 to FIG. 11 are each a schematic structural diagram of another semiconductor device during manufacturing according to an embodiment of the present application.

### DETAILED DESCRIPTION

In order to make the objectives, technical solutions and advantages of the embodiments of the present application clearer, the following clearly and completely describes the technical solutions in the embodiments of the present application with reference to the accompanying drawings in the embodiments of the present application. Apparently, the described embodiments are some rather than all of the embodiments of the present application. All other embodiments obtained by those of ordinary skill in the art based on the embodiments of the present application without creative efforts should fall within the protection scope of the present application. In addition, although disclosures in the present application are presented according to one or several exemplary examples, it should be understood that each aspect of these disclosures can also individually constitute a complete implementation.

It should be noted that brief descriptions of the terms in the present application are used only to facilitate the understanding of the implementations described below, and are not intended to limit the implementations of the present application. Unless otherwise stated, these terms should be understood according to their ordinary and usual meanings.

In this specification, the claims, and the accompanying drawings of the present application, the terms “first”, “second”, and so on are intended to distinguish similar or like objects or entities but do not necessarily indicate a specific order or sequence, unless otherwise noted. It should be understood that the terms used in such a way are interchangeable in proper circumstances, for example, can enable implementation in other sequences than those illustrated or described in the embodiments of the present application.

In addition, the terms “including” and “having” and any variations thereof are intended to cover non-exclusive inclusion. For example, for products or devices that include a series of components, the components are not necessarily limited to those clearly listed, but may include other components not clearly listed or inherent to these products or devices.

During development of a dynamic random access memory (DRAM), an HKMG technology starts to be applied in a peripheral region to meet high-performance requirements of reducing an equivalent oxide thickness (EOT) and a leakage current of a device.

However, due to an interface effect between a high-k dielectric (HK) layer and a silicon substrate, it is difficult to directly adjust a threshold voltage of the device through conventional ion implantation, and the limitation of mobility of hole-type carriers in the silicon substrate makes it more difficult to adjust a threshold voltage of a PMOS.

Because a SiGe multilayer film structure provides a possibility of adjusting a silicon energy band structure and enhancing the mobility, a strained silicon technology SiGe has begun to be used in the manufacture of an HKMG PMOS.

In a PMOS manufacturing process, after a SiGe epitaxial layer is selectively grown in a PMOS region, it is also necessary to remove oxide grown in a negative-channel metal-oxide semiconductor (NMOS) region. In a feasible implementation, a photoresist needs to be formed on a surface of the SiGe epitaxial layer in the PMOS region before the oxide grown in the NMOS region is removed. Subsequently, the oxide in the NMOS region is removed by using an etching technology, and then the photoresist on the surface of the SiGe epitaxial layer in the PMOS region is removed.

The photoresist on the surface of the SiGe epitaxial layer may be removed mainly in the following two manners:

Manner 1. Acid treatment: A common condition is to insert a mixed solution of sulfuric acid and hydrogen peroxide and raise a temperature to 80° C. In order to completely clean the photoresist, an over etching (over strip) manner is often used, easily causing sulfuric acid and hydrogen peroxide to directly contact the surface of the SiGe epitaxial layer and oxidize the surface of the SiGe epitaxial layer, resulting in degradation of performance of the device.

Manner 2. Oxidizing gas treatment: Plasma oxygen is injected into a device processing chamber to oxidize the photoresist, and remaining substances are removed through high-temperature ablation. However, the plasma oxygen reacts with the surface of the SiGe epitaxial layer during removal. Consequently, damage is also caused to a trench surface of the device, and the performance of the device is degraded.

In order to resolve the foregoing technical problems, the embodiments of the present application provide another semiconductor device and a method of manufacturing semiconductor device. Through formation of a protective layer on the surface of the SiGe epitaxial layer, the surface of the SiGe epitaxial layer can be effectively protected from being damaged during manufacturing of a PMOS device, and carrier mobility of the PMOS device can be improved, thereby improving performance of the PMOS device. Details are described through the following embodiments.

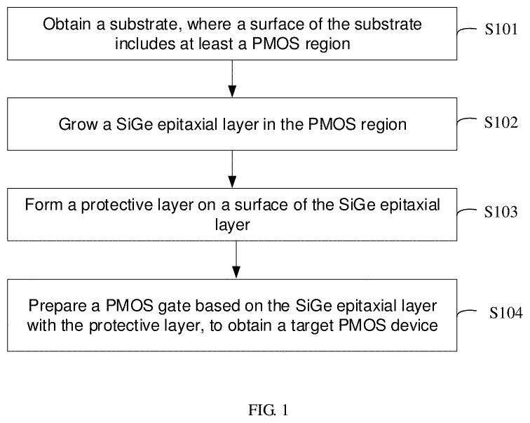

FIG. 1 is a schematic flowchart of a method of manufacturing semiconductor device according to an embodiment of the present application. Referring to FIG. 1, in a feasible implementation of the present application, the method of manufacturing semiconductor device includes:

S101. Obtain a substrate, where a surface of the substrate includes at least a PMOS region.

Optionally, the substrate may be an n-type silicon substrate.

S102. Grow a SiGe epitaxial layer in the PMOS region.

In this embodiment of the present application, the SiGe epitaxial layer may be grown in the PMOS region by using a selective epitaxial growth process.

The selective epitaxial growth process may be understood as epitaxial growth performed within a defined region on the substrate.

A thickness of the SiGe epitaxial layer depends on a concentration of Ge. A lower concentration of Ge indicates a thicker SiGe epitaxial layer that can be grown, and vice versa.

S103. Form a protective layer on a surface of the SiGe epitaxial layer.

In another embodiment of the present application, a protective layer can be formed on the surface of the SiGe epitaxial layer after the SiGe epitaxial layer is grown in the PMOS region, to protect the surface of the SiGe epitaxial layer against impact of a subsequent manufacturing process.

It can be understood that, the protective layer needs to be capable of resisting a certain concentration of a mixed solution of sulfuric acid and hydrogen peroxide and needs to resist a certain concentration of oxidizing gas, so that when the mixed solution of sulfuric acid and hydrogen peroxide is used to clean a photoresist in the PMOS region, or when the oxidizing gas is used to remove a photoresist in the PMOS region, the protective layer can isolate the SiGe epitaxial layer from the mixed solution of sulfuric acid and hydrogen peroxide, or from the oxidizing gas, thereby protecting the surface of the SiGe epitaxial layer.

For example, the protective layer may be oxide such as silicon oxide.

S104. Prepare a PMOS gate based on the SiGe epitaxial layer with the protective layer, to obtain a target PMOS device.

In this embodiment of the present application, a PMOS gate can be prepared based on the SiGe epitaxial layer with the protective layer after the protective layer is formed on the surface of the SiGe epitaxial layer. Due to existence of the protective layer, damage to the surface of the SiGe epitaxial layer can be effectively reduced during subsequent preparation.

That is, in the another semiconductor device and the method of manufacturing semiconductor device provided in the embodiments of the present application, through formation of a protective layer on the surface of the SiGe epitaxial layer, during manufacturing of a PMOS device, the surface of the SiGe epitaxial layer can be effectively protected from damage, and carrier mobility of the PMOS device can be improved, thereby improving electrical properties of the PMOS device. Details are described through the following embodiments.

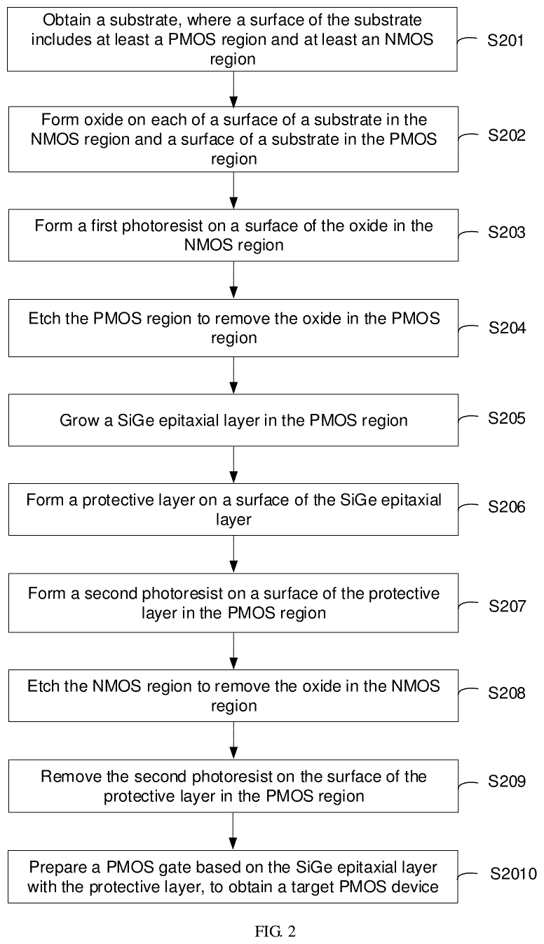

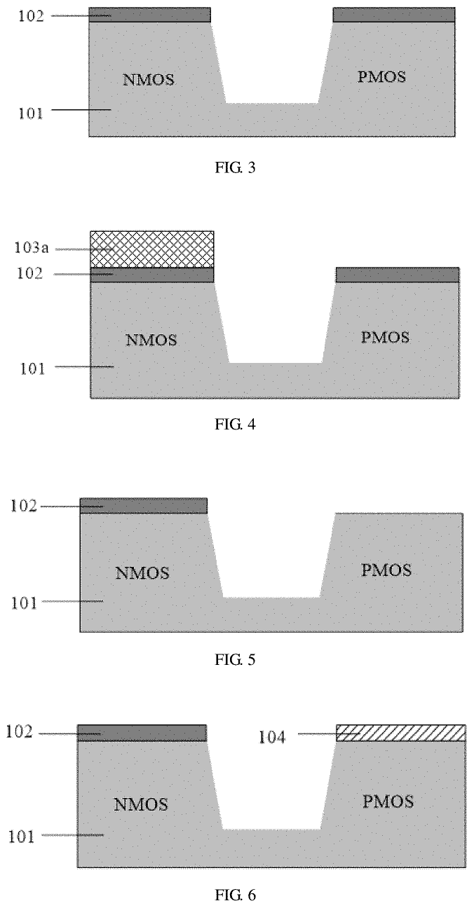

Refer to FIG. 2 based on the content described in the foregoing embodiment. FIG. 2 is another schematic flowchart of another method of manufacturing semiconductor device according to an embodiment of the present application. Also refer to FIG. 3 to FIG. 11, which are each a schematic structural diagram of another semiconductor device during manufacturing according to an embodiment of the present application.

In another feasible implementation of the present application, the method of manufacturing semiconductor device includes:

S201. Obtain a substrate, where a surface of the substrate includes at least a PMOS region and at least an NMOS region.

S202. Form oxide on a surface of a substrate in the NMOS region and a surface of a substrate in the PMOS region.

Referring to FIG. 3 for details, a layer of oxide 102 is thermally grown in situ on an upper surface of the substrate 101, and the oxide 102 is distributed in both the NMOS region and the PMOS region.

S203. Form a first photoresist on a surface of the oxide in the NMOS region.

In a feasible implementation, a photoresist may be formed on the surface of the oxide in the NMOS region and the PMOS region at the same time, and then the photoresist in the PMOS region is removed, retaining only the photoresist in the NMOS region, that is, the first photoresist is formed on the surface of the oxide in the NMOS region. Referring to FIG. 4 for details, a photoresist 103a is formed on the surface of the oxide in the NMOS region.

S204. Etch the PMOS region to remove the oxide in the PMOS region.

In a feasible implementation, the first photoresist in the NMOS region is removed after the oxide in the PMOS region is removed. Referring to FIG. 5 for details, a photoresist 103a on the surface of the oxide in the NMOS region is removed after the oxide in the PMOS region is removed by using an etching technology.

S205. Grow a SiGe epitaxial layer in the PMOS region.

Referring to FIG. 6 for details, a SiGe epitaxial layer 104 is selectively grown in the PMOS region.

S206. Form a protective layer on a surface of the SiGe epitaxial layer.

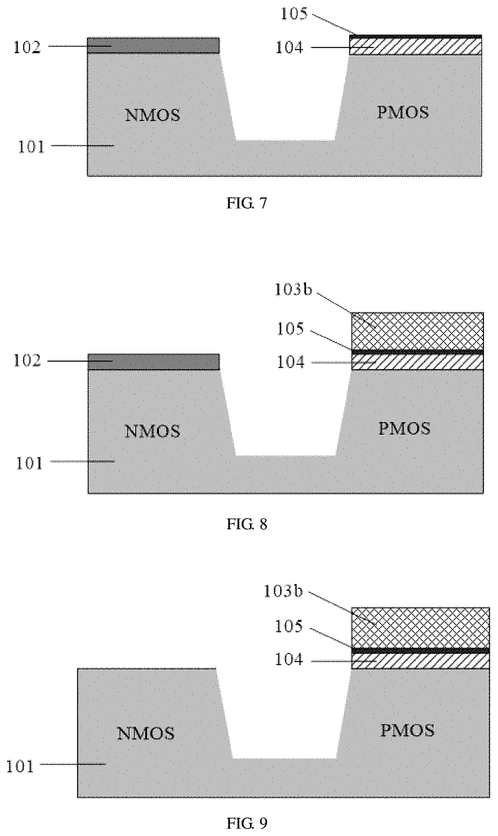

Referring to FIG. 7 for details, the protective layer 105 is formed on the surface of the SiGe epitaxial layer 104.

In a feasible implementation, the surface of the SiGe epitaxial layer 104 may be oxidized by using a pre-configured oxidizer, such that the protective layer 105 is formed on the surface of the SiGe epitaxial layer 104.

For example, the surface of the SiGe epitaxial layer 104 may be cleaned by using a pre-configured SC1 solution, such that the protective layer 105 is formed on the surface of the SiGe epitaxial layer 104.

It can be understood that, cleaning the surface of the SiGe epitaxial layer by using the SC1 solution can cause Si to be oxidized to form a layer of oxide SiOₓ, and existence of Ge has a catalytic effect on this process and Ge is repelled and enriched under SiOₓ due to the production of SiOₓ on the surface.

In some embodiments, during cleaning of the SiGe epitaxial layer by using the SC1 solution, an optimal oxide layer protection effect can also be achieved by selecting an appropriate SC1 solution ratio and cleaning time. For example, a thin layer of silicon oxide formed by SC1 oxidation can effectively reduce a SiGe oxidation rate, control the oxidation process, and can effectively prevent the SiGe surface from being damaged in a subsequent etching process.

Optionally, components of the SC1 solution include ammonia water, hydrogen peroxide, and water.

S207. Form a second photoresist on a surface of the protective layer in the PMOS region.

Referring to FIG. 8 for details, the second photoresist 103b is formed on the surface of the protective layer 105 in the PMOS region.

In this embodiment of the present application, a photoresist may be first coated on the surface of the protective layer in the PMOS region and the surface of the oxide in the NMOS region at the same time, and then the photoresist on the surface of the oxide in the NMOS region is removed, retaining only the second photoresist 103b on the surface of the protective layer in the PMOS region.

S208. Etch the NMOS region to remove the oxide in the NMOS region.

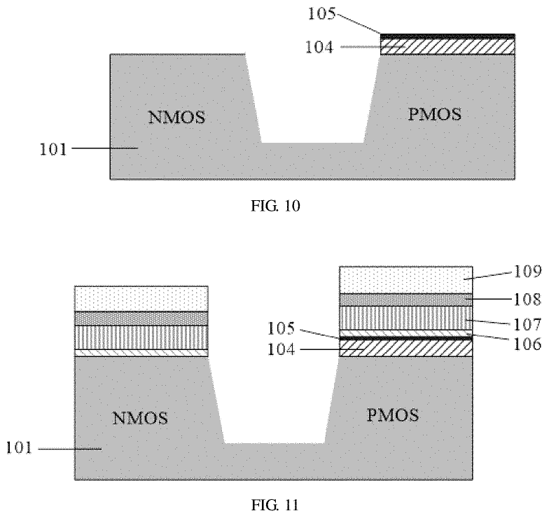

Referring to FIG. 9 for details, the NMOS region is etched to remove the oxide 102 in the NMOS region.

S209. Remove the second photoresist on the surface of the protective layer in the PMOS region.

Referring to FIG. 10 for details, the second photoresist 103b on the surface of the protective layer 105 in the PMOS region can be removed after the oxide in the NMOS region is removed.

S2010. Prepare a PMOS gate based on the SiGe epitaxial layer with the protective layer, to obtain a target PMOS device.

In a feasible implementation, an oxide layer, an HK layer, and a conductive layer may be sequentially prepared on the surface of the protective layer in the NMOS region and the PMOS region, to form an NMOS gate and a PMOS gate.

Optionally, the HK layer includes one or more of hafnium oxide, doped hafnium oxide, zirconium oxide, aluminum oxide, or lanthanum oxide. The conductive layer includes a metal barrier layer and a metal conductive layer. Materials of the metal barrier layer include one or more of titanium nitride, tungsten nitride, tantalum nitride, or molybdenum nitride. Materials of the metal conductive layer include one or more of tungsten, polycrystalline silicon, or titanium-silicon nitride.

Referring to FIG. 11 for details, after the NMOS region is etched to remove the oxide 102 in the NMOS region, an oxide layer 106 may be formed on the surface of the protective layer in the NMOS region and the PMOS region, and then an HK layer 107, a metal barrier layer 108, and a metal conductive layer 109 are sequentially prepared on a surface of the oxide layer 106 in the NMOS region and the PMOS region, to form an NMOS gate and a PMOS gate.

In another feasible implementation, alternatively, the protective layer 105 on the PMOS may be removed with hydrofluoric acid first, and then the PMOS gate is prepared to obtain the target PMOS device.

In the method of manufacturing semiconductor device provided in this embodiment of the present application, through formation of a protective layer on a surface of a SiGe epitaxial layer, during manufacturing of a PMOS device, the surface of the SiGe epitaxial layer can be effectively protected from damage, and carrier mobility of the PMOS device can be improved, thereby improving electrical properties of the PMOS device.

Based on the content described in the foregoing embodiment, an embodiment of the present application further provides a semiconductor device. The semiconductor device includes:

a substrate, where a surface of the substrate includes at least a PMOS region;

a SiGe epitaxial layer, grown on the surface of the substrate and located in the PMOS region;

a protective layer, covering a surface of the SiGe epitaxial layer; and

a PMOS gate, located on a surface of the protective layer.

It can be understood that, according to the semiconductor device provided in this embodiment of the present application, the protective layer on the surface of the SiGe epitaxial layer can effectively protect the surface of the SiGe epitaxial layer from being damaged during process manufacturing, thereby helping improve carrier mobility of the PMOS device, and improving electrical properties of the PMOS device.

In a feasible implementation, the protective layer is formed by an oxidation reaction between a pre-configured oxidizer and the SiGe epitaxial layer.

Optionally, the oxidizer may be an SC1 solution.

Optionally, components of the SC1 solution include ammonia water, hydrogen peroxide, and water.

In a feasible implementation, a material of the protective layer may be silicon oxide.

In a feasible implementation, the semiconductor device further includes at least an NMOS region, and an NMOS gate is formed in the NMOS region.

In a feasible implementation, as shown in FIG. 11, the PMOS gate and the NMOS gate each include an oxide layer 106, an HK layer 107, a metal barrier layer 108, and a metal conductive layer 109.

Optionally, materials of the metal barrier layer 108 include one or more of titanium nitride, tungsten nitride, tantalum nitride, or molybdenum nitride. Materials of the metal conductive layer 109 include one or more of tungsten, polycrystalline silicon, or titanium-silicon nitride.

Finally, it should be noted that the above embodiments are merely used to explain the technical solutions of the present application, but are not intended to limit the present application. Although the present application is described in detail with reference to the foregoing embodiments, those of ordinary skill in the art should understand that they can still modify the technical solutions described in the foregoing embodiments, or make equivalent substitutions on some or all technical features therein. These modifications or substitutions do not make the essence of the corresponding technical solutions deviate from the spirit and scope of the technical solutions of the embodiments of the present application.

1. A method of manufacturing semiconductor device, comprising:
obtaining a substrate, wherein a surface of the substrate comprises at least a positive-channel metal-oxide semiconductor (PMOS) region;
growing a silicon-germanium (SiGe) epitaxial layer in the PMOS region;
forming a protective layer on a surface of the SiGe epitaxial layer; and
preparing a PMOS gate based on the SiGe epitaxial layer with the protective layer, to obtain a target PMOS device.

2. The method of manufacturing semiconductor device according to claim 1, wherein the forming a protective layer on a surface of the SiGe epitaxial layer comprises:
oxidizing the surface of the SiGe epitaxial layer by using a pre-configured oxidizer, to form the protective layer on the surface of the SiGe epitaxial layer.

3. The method of manufacturing semiconductor device according to claim 2, wherein the oxidizing the surface of the SiGe epitaxial layer by using a pre-configured oxidizer comprises:
cleaning the surface of the SiGe epitaxial layer by using a pre-configured SC1 solution, wherein components of the pre-configured SC1 solution comprise ammonia water, hydrogen peroxide, and water.

4. The method of manufacturing semiconductor device according to claim 3, wherein a material of the protective layer comprises silicon oxide.

5. The method of manufacturing semiconductor device according to claim 1, wherein the surface of the substrate further comprises at least a negative-channel metal-oxide semiconductor (NMOS) region, and before the growing a silicon-germanium (SiGe) epitaxial layer in the PMOS region, the method of manufacturing semiconductor device further comprises:
etching the PMOS region to remove oxide in the PMOS region; and
removing a first photoresist in the NMOS region.

6. The method of manufacturing semiconductor device according to claim 5, wherein before the etching the PMOS region to remove oxide in the PMOS region, the method of manufacturing semiconductor device further comprises:
forming oxide on a surface of a substrate in the NMOS region and a surface of a substrate in the PMOS region;
forming a first photoresist on the oxide; and
removing a first photoresist in the PMOS region.

7. The method of manufacturing semiconductor device according to claim 6, wherein before the preparing a PMOS gate based on the SiGe epitaxial layer with the protective layer, the method of manufacturing semiconductor device further comprises:
forming a second photoresist on a surface of the protective layer in the PMOS region and a surface of the oxide in the NMOS region;
removing the second photoresist on the surface of the oxide in the NMOS region;
etching the NMOS region to remove the oxide in the NMOS region; and
removing the second photoresist on the surface of the protective layer in the PMOS region.

8. The method of manufacturing semiconductor device according to claim 1, wherein the preparing a PMOS gate based on the SiGe epitaxial layer with the protective layer comprises:
sequentially preparing an oxide layer, a high-k dielectric (HK) layer, and a conductive layer on a surface of the protective layer, to form the PMOS gate.

9. The method of manufacturing semiconductor device according to claim 8, wherein the preparing a PMOS gate based on the SiGe epitaxial layer with the protective layer further comprises:
sequentially preparing an oxide layer, an HK layer, and a conductive layer in an NMOS region, to form an NMOS gate.

10. The method of manufacturing semiconductor device according to claim 9, wherein the conductive layer comprises a metal barrier layer and a metal conductive layer, the metal barrier layer is located between the HK layer and the metal conductive layer; and materials of the metal barrier layer comprise one or more of titanium nitride, tungsten nitride, tantalum nitride, or molybdenum nitride, and materials of the metal conductive layer comprise one or more of tungsten, polycrystalline silicon, or titanium-silicon nitride.

11. A semiconductor device, comprising:
a substrate, wherein a surface of the substrate comprises at least a positive-channel metal-oxide semiconductor (PMOS) region;
a silicon-germanium (SiGe) epitaxial layer, grown on the surface of the substrate and located in the PMOS region;
a protective layer, covering a surface of the SiGe epitaxial layer; and
a PMOS gate, located on a surface of the protective layer.

12. The semiconductor device according to claim 11, wherein the protective layer is formed by an oxidation reaction between a pre-configured oxidizer and the SiGe epitaxial layer.

13. The semiconductor device according to claim 12, wherein the oxidizer is an SC1 solution, and components of the SC1 solution comprise ammonia water, hydrogen peroxide, and water.

14. The semiconductor device according to claim 13, wherein a material of the protective layer comprises silicon oxide.

15. The semiconductor device according to claim 11, wherein the PMOS gate comprises an oxide layer, a high-k dielectric (HK) layer, and a conductive layer; and the HK layer is located between the protective layer and the conductive layer.

16. The semiconductor device according to claim 15, wherein the surface of the substrate further comprises at least a negative-channel metal-oxide semiconductor (NMOS) region; and an NMOS gate is formed in the NMOS region.

17. The semiconductor device according to claim 16, wherein the NMOS gate comprises an oxide layer, an HK layer, and a conductive layer.

18. The semiconductor device according to claim 17, wherein the conductive layer comprises a metal barrier layer and a metal conductive layer; and the metal barrier layer is located between the HK layer and the metal conductive layer; and materials of the metal barrier layer comprise one or more of titanium nitride, tungsten nitride, tantalum nitride, or molybdenum nitride; and materials of the metal conductive layer comprise one or more of tungsten, polycrystalline silicon, or titanium-silicon nitride.
